(19) United States
(12) Patent Application Publication
(10) Pub. No.: US 2026/0159949 A1
(43) Pub. Date: Jun. 11, 2026

(54) METHODS AND APPARATUS FOR TEMPERATURE DISTRIBUTION

(71) Applicant: ASM IP Holding B.V., Almere (NL)

(72) Inventors: Xu Huang, Mesa, AZ (US); Shuyang Zhang, Chandler, AZ (US); Ali Al janabi, Scottsdale, AZ (US); Estiaque Haidar Shourov, Mesa, AZ (US); Jian-Wei Liang, Hsinchu (TW); Mojtaba Samiee, Tempe, AZ (US)

(21) Appl. No.: 19/407,095

(22) Filed: Dec. 3, 2025

Related U.S. Application Data
(60) Provisional application No. 63/728,818, filed on Dec. 6, 2024.

(51) Int. Cl. C23C 16/458

(52) U.S. Cl. CPC C23C 16/4582

(57) ABSTRACT

Various embodiments of the present technology may provide a radiation shield formed from a body having a plurality of cutouts. The radiation shield may also include a plurality of removable segments that are shaped to be disposed within the cutouts.

### CROSS-REFERENCE TO RELATED APPLICATIONS

This application is a nonprovisional of, and claims priority to and the benefit of, U.S. Provisional Patent Application No. 63/728,818 , filed Dec. 6, 2024 and entitled “METHODS AND APPARATUS FOR TEMPERATURE DISTRIBUTION,” which is hereby incorporated by reference herein.

### FIELD OF INVENTION

The present disclosure generally relates to a method and apparatus for temperature distribution. More particularly, the present disclosure relates to a radiation shield disposed below a susceptor in a lower chamber of a reactor.

### BACKGROUND OF THE TECHNOLOGY

Film non-uniformity patterns on a wafer may be caused, in part, by temperature gradients within the reactor. In many cases, the susceptor heats the wafer during processing, however, heat loss at the susceptor may create undesired temperature non-uniformity across the susceptor and the wafer.

### SUMMARY OF THE INVENTION

Various embodiments of the present technology may provide a radiation shield formed from a body having a plurality of cutouts. The radiation shield may also include a plurality of removable segments that are shaped to be disposed within the cutouts.

According to one aspect, an apparatus comprises: a body comprising a plurality of cutouts arranged within a plurality of circular zones; and a plurality of removable segments, each segment disposed within one of the plurality of cutouts.

In one embodiment, the plurality of circular zones comprises at least 2 circular zones.

In one embodiment, the apparatus further comprises a plurality of stabilizers arranged on a bottom surface of the body, wherein the stabilizers extend toward the cutout.

In one embodiment, the plurality of removable segments directly contact at least one of the stabilizers from the plurality of stabilizers.

In one embodiment, the body is formed from a metal material comprising at least one of aluminum, nickel, or tungsten.

In one embodiment, the plurality of removable segments is in a range of 20-48 segments.

In one embodiment, each segment from the plurality of removable segments comprises a first surface having a first emissivity and a second opposing surface having a second emissivity.

In one embodiment, the first emissivity is different from the second emissivity.

In one embodiment, the number of cutouts is equal to the number of removable segments.

In one embodiment, each cutout comprises an interior-facing edge comprising a groove.

In one embodiment, each segment comprises an outer edge comprising a protrusion that is sized to mate with the groove.

In one embodiment, the body has a height in a range of 1 mm to 2 mm, and each segment has a height in a range of 1 mm to 2 mm.

In yet another aspect, a system comprises: a reaction chamber comprising a support assembly, the support assembly comprising a pedestal and a susceptor coupled to the pedestal; and a plate coupled to the support assembly, the plate comprising: a body comprising a pocket; and a plurality of removable segments disposed within the pocket.

In one embodiment, each segment comprises a main body and lip that extends outwards from the main body.

In one embodiment, the lip of one segment overlaps with the lip of an neighboring segment.

In one embodiment, a first segment from the plurality of removable segments has a first emissivity and a second segment from the plurality of removable segments has a second emissivity.

In one embodiment, the plate has a height in a range of 1 mm to 2 mm.

In another aspect, a system comprises: a reaction chamber comprising a support assembly, the support assembly comprising a pedestal and a susceptor coupled to the pedestal; and a plate coupled to the support assembly, the plate comprising: a body comprising: a plurality of cutouts, wherein a first cutout is arranged at a geometric center of the plate, and a second cutout is arranged adjacent to the first cutout and has an arch shape; and at least one region, on an upward-facing surface of the body, having a different emissivity than a remaining area of the upward-facing surface.

In one embodiment, the plate has a thickness in a range of 1 mm to 2 mm.

In one embodiment, the cutout has a width in a range of 5 mm to 30 mm.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a top view of a radiation shield in accordance with embodiments of the present technology;

FIG. 3 is a perspective view of the radiation shield in accordance with embodiments of the present technology;

FIG. 4 is a bottom view of a portion of the radiation shield in accordance with embodiments of the present technology;

FIG. 5 is a partial cross-sectional view of the radiation shield in accordance with embodiments of the present technology;

FIG. 6A is a cross-sectional view of the radiation shield in accordance with embodiments of the present technology;

FIG. 6B is a partial cross-sectional view of the radiation shield in accordance with embodiments of the present technology;

FIGS. 7A and 7B are perspective views of the radiation shield in accordance with embodiments of the present technology; and

FIG. 8 is a perspective view of the radiation shield in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, vessels, and susceptors.

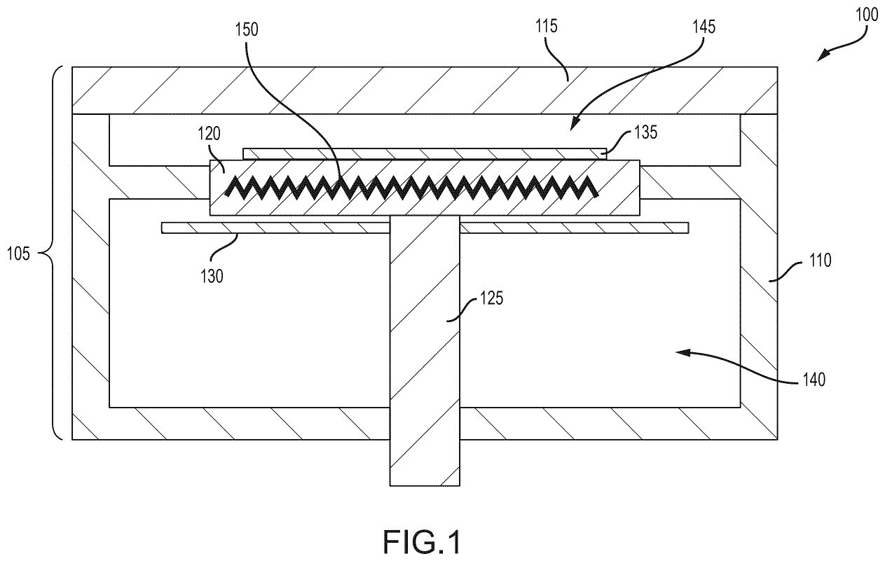

Referring to FIG. 1, an exemplary system 100 may comprise a reactor 105 configured to perform processing on an object to be processed, such as a substrate 135, e.g., a wafer. For example, the reactor 105 may be configured to perform heating, deposition, etching, polishing, ion implantation, and/or other processing on the object to be processed. In some embodiments, the reactor 105 may be configured to perform a movement function, a vacuum sealing function, and an exhaust function. In some embodiments, the reactor 105 may perform an atomic layer deposition (ALD) process or a chemical vapor deposition (CVD) process.

In various embodiments, the reactor 105 may comprise a reaction chamber 110 and a showerhead 115. The reaction chamber 110 may comprise sidewalls that form a lower chamber volume 140. The showerhead 115 may be configured to deliver a vapor into the reaction chamber 110. In particular, the showerhead 115 may be configured to deliver the vapor into a reaction space 145 where the substrate 135 is positioned during a deposition process or other process. The showerhead 115 together with the reaction chamber 110 form an enclosed space, which includes the lower chamber volume 140 and the reaction space 145.

In various embodiments, the showerhead 115 may be disposed on a top surface of the reaction chamber 110. In some embodiments, the showerhead115 may be fastened to the sidewalls, however, in other cases, the showerhead 115 may merely rest on the sidewalls of the reaction chamber 110.

In various embodiments, the system 100 may further comprise a support assembly disposed within the reactor 105. The support assembly may comprise a susceptor 120 having a surface for supporting the substrate 135 and a pedestal 125 coupled to the susceptor 120. In various embodiments, the susceptor 120 may comprise a heating element 150 for heating the substrate 135. For example, the heating element 150 may comprise a resistive heating element or any other suitable heating element. The heating element 150 may be embedded within the susceptor 120.

For loading/unloading of the substrate 135, the support assembly may be configured to be vertically movable (up and down) by being connected to a driving unit (not shown). For example, the pedestal 125 may be coupled to the driving unit, such that the pedestal 125 and susceptor 120 move together.

In various embodiments, the support assembly may be arranged within the lower chamber 140 of the reaction chamber 110. For example, the pedestal 125 be arranged in the lower chamber 140 while the susceptor 120 may be exposed to both the lower chamber 140 and the reaction space 145 depending on the position of the support assembly. FIG. 1 illustrates the support assembly in a processing position, which is the position of the support assembly and susceptor 120 during a deposition process.

In addition, the reaction space 145 may be formed by the susceptor 120 and the showerhead 115 when the susceptor 120 is the processing position. In some embodiments, the reaction space 145 may also be formed by portions of the reaction chamber 110, such as the sidewalls of the reaction chamber 110, and/or other components within the reaction chamber 110, such as a spacer plate (not shown) or a flow control ring (not shown).

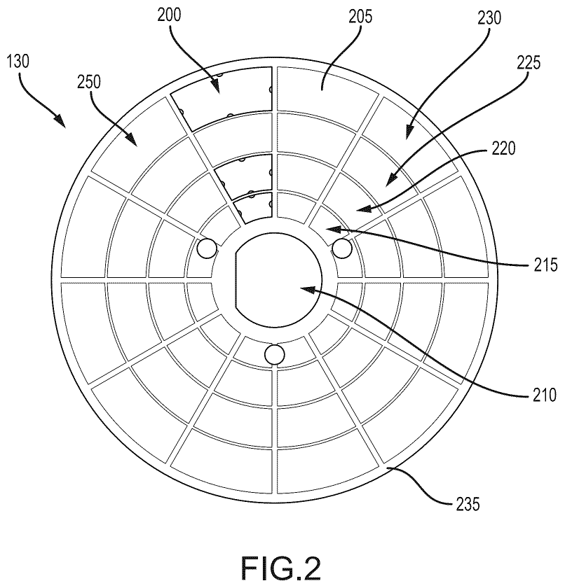

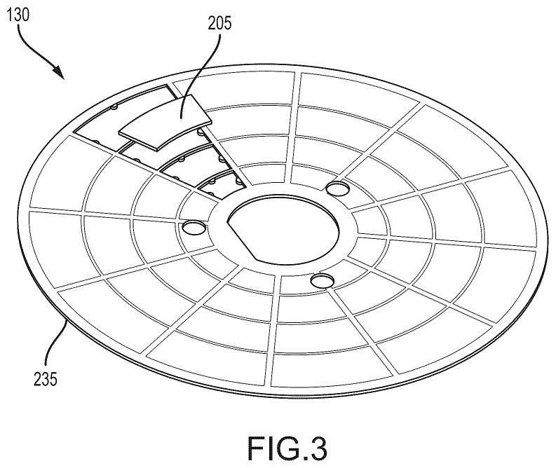

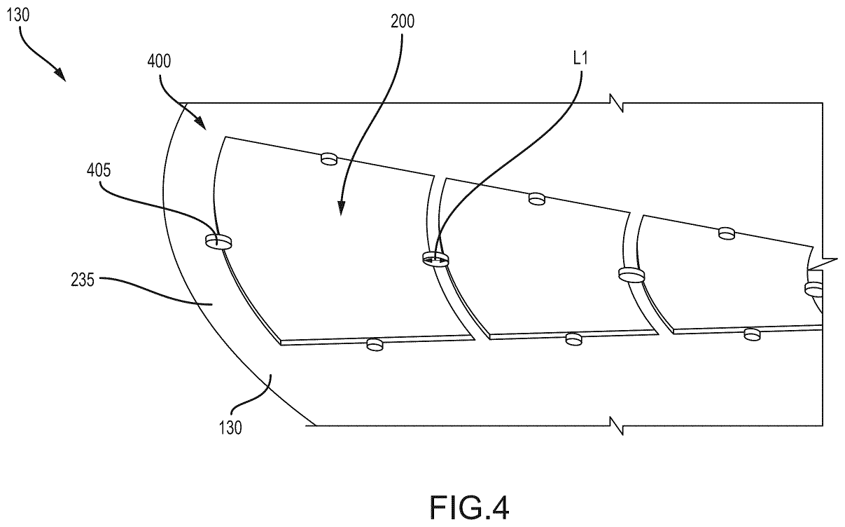

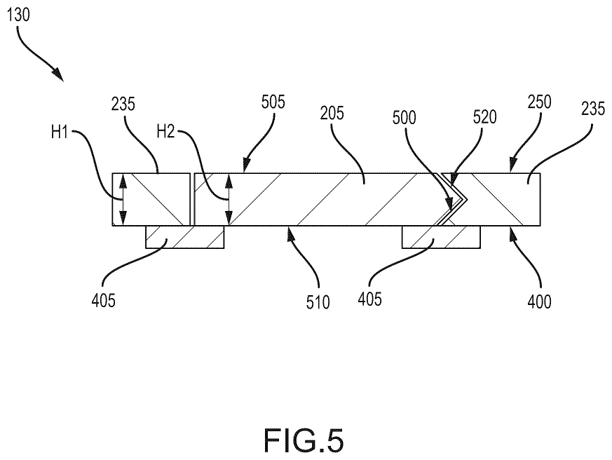

In various embodiments, and referring to FIGS. 1-7, the system 100 may further comprise a radiation shield 130 to provide temperature distribution and regulation to the susceptor 120. The radiation shield 130 may be formed from a metallic material, such as aluminum, nickel, tungsten, or a metal alloy. The radiation shield 130 may be disposed in the lower chamber 140 of the reaction chamber 110, opposite the reaction space 145, and adjacent to a bottom surface of the susceptor 120. In addition, the radiation shield 130 may be coupled to the support assembly. For example, the radiation shield 130 may be fastened to the susceptor 120 and/or the pedestal 125 with bolts or the like. The radiation shield 130 may have a height in the range of 1 mm to 2 mm.

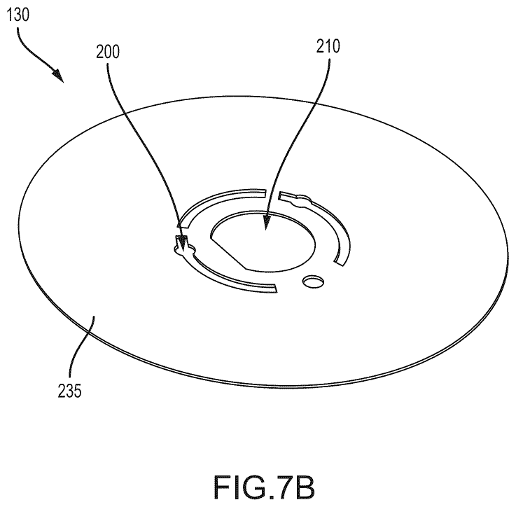

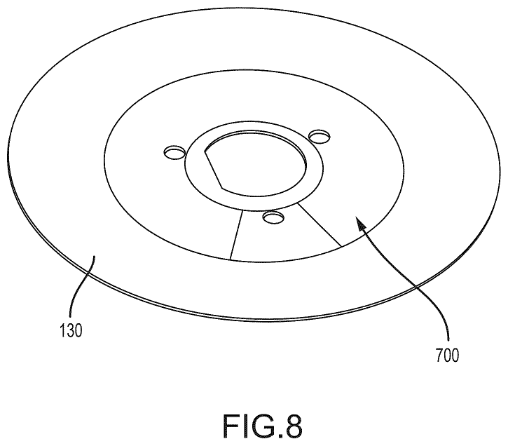

In various embodiments, the radiation shield 130 may comprise a top surface 250 and a bottom surface 400. The top surface 250 may face the bottom surface of the susceptor 120. In various embodiments, the radiation shield 130 may comprise a region having a different texture than the rest of the body 235. For example, the body 235 may comprise a region 700 having a different texture to change the emissivity of that region. For example, the region 700 may be polished or textured/roughened to change the emissivity of that region. Polishing may decrease emissivity, while texturing/roughening may increase emissivity. The region 700 may be located adjacent to the center opening 210 and may comprise any surface area. The surface area for the region 700 may be selected based on desired temperature regulation. For example, the region 700 in FIG. 7A is smaller than the region 700 in FIG. 8, wherein each pattern provides a desired temperature gradient to the wafer 135.

In various embodiments, the radiation shield 130 may comprise a body 235 and a plurality of cutouts 200 or openings within the body 235. For example, the radiation shield 130 may comprise a center opening 210 in a geometric center of the radiation shield 130. The center opening 210 may be used to receive the pedestal 125. In other words, the pedestal 125 may be inserted into the center opening 210. The body 235 may have a height H1 in the range of 1 mm to 2 mm. The body 235 may have a diameter in the range of 300 mm to 500 mm, and more particularly 380 mm to 420 mm. The body 235 may be formed from a metallic material, such as aluminum, nickel, tungsten, or a metal alloy.

In various embodiments, the cutouts 200 may be arranged in a circular pattern in a plurality of zones. For example, the radiation shield 130 may comprise one or more cutouts 200 in a first zone 215, a second zone 220 that is concentric with the first zone 215, a third zone 225 that is concentric with the second zone 220, and a fourth zone 230 that is concentric with the third zone 225. Each zone may be concentric with the center opening 210. The cutouts 200 may be any desired shape or size. In some embodiments, the cutout 200 may have a width in the range of 5 mm to 30 mm, and more particularly, 9 mm to 24 mm. The width of the cutout 200 may be selected based on the number of zones, as a higher number of zones will result in smaller widths.

In various embodiments, the radiation shield 130 may further comprise a plurality of removable segments 205. Each removable segment 205 may be shaped to be disposed within one cutout 200 from the plurality of cutouts. Each removable segment 205 may have a height H2 in the range of 1 mm to 2 mm. The removable segments 205 may be formed from a metallic material, such as aluminum, nickel, tungsten, or a metal alloy. Each segment 205 may have a different emissivity from a neighboring segment. For example, a top surface of a segment 205 may have a different emissivity from a bottom surface of the same segment 205. Emissivity may be varied by polishing (for decreased emissivity) or textured/roughened (for increased emissivity).

In various embodiments, the radiation shield 130 may further comprise a plurality of stabilizers 405 arranged on the bottom surface 400 of the body 235. The stabilizers 405 may extend inward toward the cutout 200. Each cutout 200 may have a plurality of stabilizers 405, with one stabilizer on along each edge of the cutout 200. The stabilizers 405 may support the removable segments 205. For example, the removable segment 205 may be in direct contact with the stabilizers 405 when the removable segment is disposed within the cutout 200. The stabilizers 405 may be any size or shape suitable for supporting the removable segments 205. In some embodiments, the stabilizer 405 may have a length L1 in the range of 2mm-6 mm.

In various embodiments, each cutout 200 may comprise an interior-facing edge 500 comprising a groove. The removable segment 205 may comprise an outer edge 520 that mates with the groove.

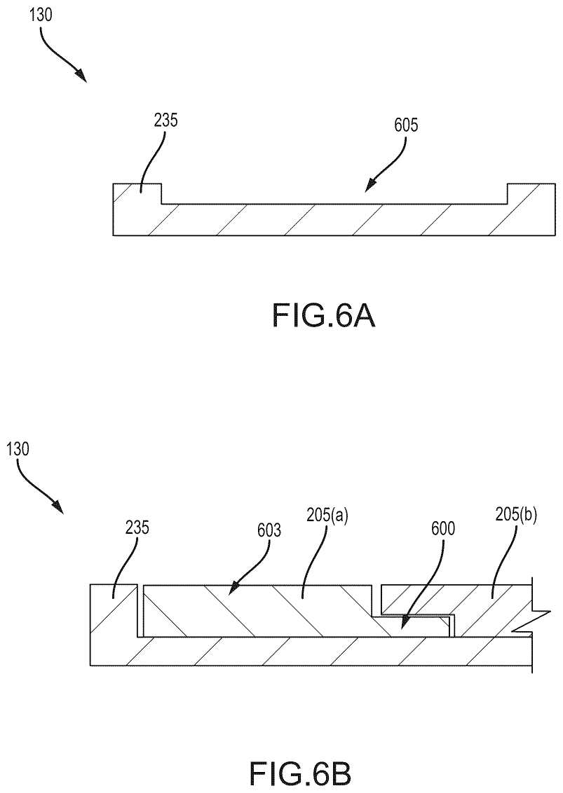

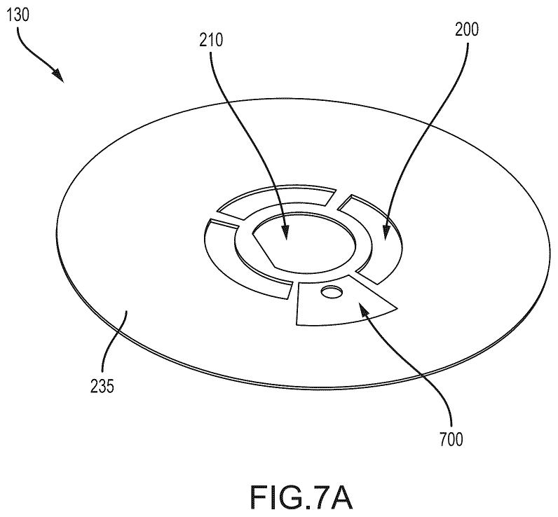

In some embodiments, and referring to FIGS. 6A-6B, the radiation shield 130 may comprise a pocket 605. In the present embodiment, the plurality of removable segments 205(a), 205(b) may be disposed within the pocket 605 and supported by the body 235, wherein that portion of the body 235 supporting the removable segment 205 is a solid, continuous material. In the present embodiment, the removable segment 205 may comprise a main body 603 and a lip 600. In the present case, the lip 600 may extend outward from the main body 603, such that the removable segment 205 forms an L-shape. In the present case, the body 235 may be formed from a metal material such as aluminum, nickel, tungsten or a combination thereof. Further, the removable segments 205(a), 205(b) may be formed from a metallic material, such as aluminum, nickel, tungsten, or a metal alloy.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a body comprising a plurality of cutouts arranged within a plurality of circular zones; and
a plurality of removable segments, each segment disposed within one of the plurality of cutouts.

2. The apparatus according to claim 1, wherein the plurality of circular zones comprises at least 2 circular zones.

3. The apparatus according to claim 1, wherein the apparatus further comprises a plurality of stabilizers arranged on a bottom surface of the body, wherein the stabilizers extend toward the cutout.

4. The apparatus according to claim 3, wherein the plurality of removable segments directly contact at least one of the stabilizers from the plurality of stabilizers.

5. The apparatus according to claim 1, wherein the body is formed from a metal material comprising at least one of aluminum, nickel, or tungsten.

6. The apparatus according to claim 1, wherein the plurality of removable segments is in a range of 20-48 segments.

7. The apparatus according to claim 1, wherein each segment from the plurality of removable segments comprises a first surface having a first emissivity and a second opposing surface having a second emissivity.

8. The apparatus according to claim 1, wherein the first emissivity is different from the second emissivity.

9. The apparatus according to claim 1, wherein the number of cutouts is equal to the number of removable segments.

10. The apparatus according to claim 1, wherein each cutout comprises an interior-facing edge comprising a groove.

11. The apparatus according to claim 10, wherein each segment comprises an outer edge comprising a protrusion that is sized to mate with the groove.

12. The apparatus according to claim 1, wherein the body has a height in a range of 1mm to 2mm, and each segment has a height in a range of 1mm to 2mm.

13. A system, comprising:
a reaction chamber comprising a support assembly, the support assembly comprising a pedestal and a susceptor coupled to the pedestal; and
a plate coupled to the support assembly, the plate comprising:
a body comprising a pocket; and
a plurality of removable segments disposed within the pocket.

14. The reactor according to claim 13, wherein each segment comprises a main body and lip that extends outwards from the main body.

15. The reactor according to claim 14, wherein the lip of one segment overlaps with the lip of an neighboring segment.

16. The reactor according to claim 13, wherein a first segment from the plurality of removable segments has a first emissivity and a second segment from the plurality of removable segments has a second emissivity.

17. The reactor according to claim 13, wherein the plate has a height in a range of 1mm to 2 mm.

18. A system, comprising:
a reaction chamber comprising a support assembly, the support assembly comprising a pedestal and a susceptor coupled to the pedestal; and
a plate coupled to the support assembly, the plate comprising:
a body comprising:
a plurality of cutouts, wherein a first cutout is arranged at a geometric center of the plate, and a second cutout is arranged adjacent to the first cutout and has an arch shape; and
at least one region, on an upward-facing surface of the body, having a different emissivity than a remaining area of the upward-facing surface.

19. The system according to claim 18, wherein the plate has a thickness in a range of 1mm to 2 mm.

20. The system according to claim 18, wherein the cutout has a width in a range of 5 mm to 30 mm.
